(19) United States
(12) Patent Application Publication
(10) Pub. No.: US 2024/0423068 A1
(43) Pub. Date: Dec. 19, 2024

(54) DISPLAY DEVICE AND METHOD OF MANUFACTURING THE SAME

(71) Applicant: Samsung Display Co., LTD., Yongin-si (KR)

(72) Inventors: Chun Gi YOU, Yongin-si (KR); Sang Yeol KIM, Yongin-si (KR)

(21) Appl. No.: 18/601,177

(22) Filed: Mar. 11, 2024

(30) Foreign Application Priority Data
Jun. 19, 2023 (KR) 10-2023-0078506

(51) Int. Cl. H10K 59/80; H10K 59/12; H10K 59/121; H10K 59/122; H10K 59/38; H10K 102/10

(52) U.S. Cl. CPC H10K 59/8723; H10K 59/1201; H10K 59/121; H10K 59/122; H10K 59/38; H10K 2102/103

(57) ABSTRACT

A display device includes: a substrate including a sub-pixel; a first pixel electrode of the sub-pixel, disposed on the substrate; a pixel defining layer disposed on the first pixel electrode, the pixel defining layer defining a first opening exposing the first pixel electrode; a separator disposed on a top surface of the pixel defining layer; an organic light-emitting part disposed on the pixel defining layer and the separator, the organic light-emitting part including a plurality of light generation layers; and a second pixel electrode disposed on the organic light-emitting part. The separator includes: a first layer disposed on the pixel defining layer; and a second layer disposed on the first layer, the second layer defining a second opening exposing the first layer.

This application claims priority to Korean Patent Application No. 10-2023-0078506, filed on Jun. 19, 2023, and all the benefits accruing therefrom under 35 U.S.C. §119, the content of which in its entirety is herein incorporated by reference.

### BACKGROUND

### 1. Field

The disclosure generally relates to a display device and a method of manufacturing the same.

### 2. Description of the Related Art

An organic light-emitting diode (“OLED”) is an active light-emitting display element, and has not only advantages of having a wide viewing angle and being excellent in contrast but also advantages of being able to be driven at a low voltage, being lightweight and thin, and having a high response speed. Accordingly, the OLED has come into the spotlight as a next-generation display element.

One pixel may have a structure in which a plurality of light-emitting layers is stacked. The plurality of light-emitting layers may be commonly provided in sub-pixels in the pixel and be continuously provided in the sub-pixels in the pixel.

### SUMMARY

As a plurality of organic light-emitting parts is commonly provided in the sub-pixels in the pixel, a lateral leakage phenomenon between adjacent sub-pixels occurs, and therefore, the luminance or color purity of a display device may be deteriorated.

Embodiments provide a display device including a separator disposed between adjacent sub-pixels so as to reduce or prevent a lateral leakage phenomenon.

Embodiments provide a method of manufacturing the display device including the separator.

In an embodiment of the disclosure, a display device includes: a substrate including a sub-pixel; a first pixel electrode of the sub-pixel, disposed on the substrate; a pixel defining layer disposed over the first pixel electrode, the pixel defining layer defining a first opening exposing the first pixel electrode; a separator disposed on a top surface of the pixel defining layer; an organic light-emitting part disposed on the pixel defining layer and the separator, the organic light-emitting part including a plurality of light generation layers; and a second pixel electrode disposed on the organic light-emitting part, where the separator includes: a first layer disposed on the pixel defining layer; and a second layer disposed on the first layer, the second layer defining a second opening exposing the first layer.

In an embodiment, the first layer may include a metal material, and the second layer may include an inorganic material.

In an embodiment, at least a portion of the second pixel electrode may be disposed in the second opening.

In an embodiment, the second pixel electrode may be disposed directly on the first layer exposed through the second opening.

In an embodiment, the organic light-emitting part may include a hole injection layer, a hole transport layer, a light-emitting layer, an electron transport layer, a charge generation layer, and an electron injection layer, which are sequentially disposed in a third direction intersecting a first direction. At least one of the hole injection layer, the hole transport layer, the light-emitting layer, the electron transport layer, the charge generation layer, and the electron injection layer may not be disposed on the first layer exposed through the second opening.

In an embodiment, the hole injection layer and the charge generation layer may not be disposed on the first layer exposed through the second opening.

In an embodiment, the display device may further include a reflective electrode of the sub-pixel, which is disposed between the substrate and the first pixel electrode.

In an embodiment, the display device may further include an inorganic layer disposed on the substrate. The substrate may include a silicon substrate. The reflective electrode may be disposed directly on the substrate.

In an embodiment, a height of the second layer in a third direction may be about 400 nanometers (nm). The second opening may have a width of about 135 nm or less.

In an embodiment, the display device may further include: an encapsulation layer disposed over the second pixel electrode; and a color filter layer including first to third color filters disposed on the encapsulation layer while being spaced apart from each other in a first direction.

In an embodiment of the disclosure, a display device includes: a substrate including a sub-pixel; a first pixel electrode of the sub-pixel, disposed on the substrate; a pixel defining layer disposed over the first pixel electrode, the pixel defining layer defining a first opening exposing the first pixel electrode; a separator disposed on a top surface of the pixel defining layer; an organic light-emitting part disposed on the pixel defining layer and the separator, the organic light-emitting part including a plurality of light generation layers; and a second pixel electrode disposed on the organic light-emitting part, where the separator includes: a first pattern and a second pattern disposed on the pixel defining layer while being spaced apart from each other in a first direction; and a first film covering the first pattern and the second pattern.

In an embodiment, the first pattern and the second pattern may include a metal material, and the first film may include an inorganic material.

In an embodiment, a recess may be defined between the first pattern and the second pattern. At least a portion of the second pixel electrode may be disposed in the recess.

In an embodiment, a height of the recess in a third direction intersecting the first direction may be about 400 nm, and a width of the recess in the first direction may be about 135 nm.

In an embodiment, the first film may include a first part covering the first pattern, a second part covering the second pattern, and a third part covering the pixel defining layer exposed between the first pattern and the second pattern.

In an embodiment, the organic light-emitting part may include a hole injection layer, a hole transport layer, a light-emitting layer, an electron transport layer, a charge generation layer, and an electron injection layer, which are sequentially disposed in a third direction intersecting the first direction. At least one of the hole injection layer, the hole transport layer, the light-emitting layer, the electron transport layer, the charge generation layer, and the electron injection layer may not be disposed on the third part of the first film.

In an embodiment, the hole injection layer and the charge generation layer may not be disposed on the third part of the first film.

In an embodiment, the second pixel electrode may be disposed directly on the third part of the first film.

In an embodiment of the disclosure, a method of manufacturing a display device includes: forming a first pixel electrode of a sub-pixel on a substrate; forming a pixel defining layer defining a first opening exposing the first pixel electrode; forming a first layer on a top surface of the pixel defining layer; forming, on the first layer, a second layer defining a second opening exposing the first layer; forming an organic light-emitting part disposed on the first layer and the second layer, the organic light-emitting part including a plurality of light generation layers; and forming a second pixel electrode on the organic light-emitting part, where a height of the second layer is in proportion to a height of the organic light-emitting part.

In an embodiment, the forming the second layer defining the second opening may include: forming an inorganic layer on the first layer; and defining the second opening by etching and removing a portion of the inorganic layer.

### BRIEF DESCRIPTION OF THE DRAWINGS

The above and other features of embodiments of the invention will become more apparent by describing in further detail embodiments thereof with reference to the accompanying drawings, in which:

FIG. 1 is a schematic plan view illustrating an embodiment of a display device in accordance with the disclosure.

FIGS. 2A to 2C are plan views illustrating embodiments of a pixel shown in FIG. 1.

FIG. 3 is a circuit diagram illustrating an embodiment of a sub-pixel included in the pixel shown in FIGS. 2A to 2C.

FIG. 4 is a cross-sectional view illustrating an embodiment of a light-emitting element shown in FIG. 3.

FIG. 5 is a cross-sectional view illustrating another embodiment of the light-emitting element shown in FIG. 3.

FIG. 6 is a cross-sectional view illustrating a stacked structure of a pixel including the light-emitting element shown in FIG. 3.

FIG. 7 is a cross-sectional view illustrating an embodiment of the pixel shown in FIG. 6.

FIG. 8 is an enlarged view illustrating an embodiment of area A shown in FIG. 7.

FIG. 9 is a cross-sectional view illustrating some components of an organic light-emitting part disposed on a first layer and a second layer, which are shown in FIG. 8.

FIG. 10 is a cross-sectional view illustrating an embodiment of the pixel shown in FIG. 6.

FIG. 11 is an enlarged view illustrating an embodiment of area B shown in FIG. 10.

FIGS. 12 to 17 are schematic cross-sectional views illustrating an embodiment of a method of manufacturing a display device in accordance with the disclosure.

FIGS. 18 and 19 illustrate embodiments of an electronic device including the display device shown in FIG. 1.

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Like numbers refer to like elements throughout. In the drawings, the thickness of certain lines, layers, components, elements or features may be exaggerated for clarity. It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the invention.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

In the entire specification, when an element is referred to as being “connected” or “coupled” to another element, it can be directly connected or coupled to the another element or be indirectly connected or coupled to the another element with one or more intervening elements interposed therebetween.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Hereinafter, embodiments of the invention will be described in detail with reference to the accompanying drawings.

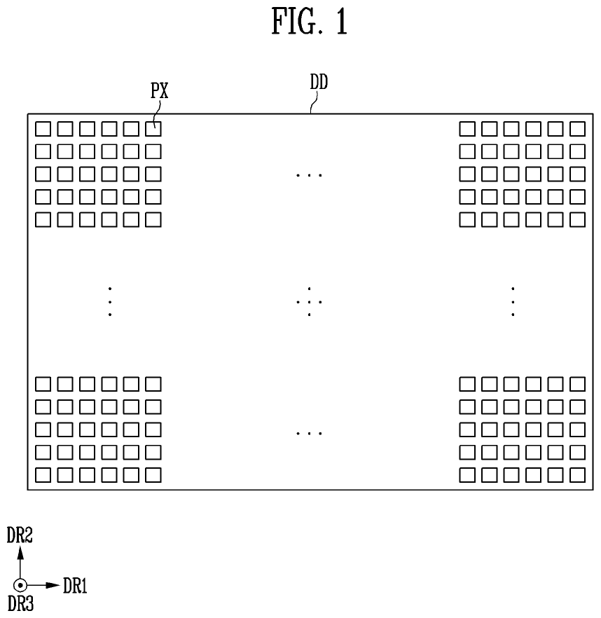

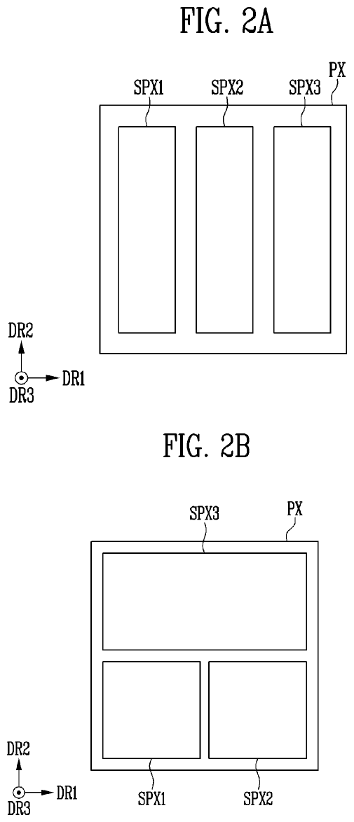

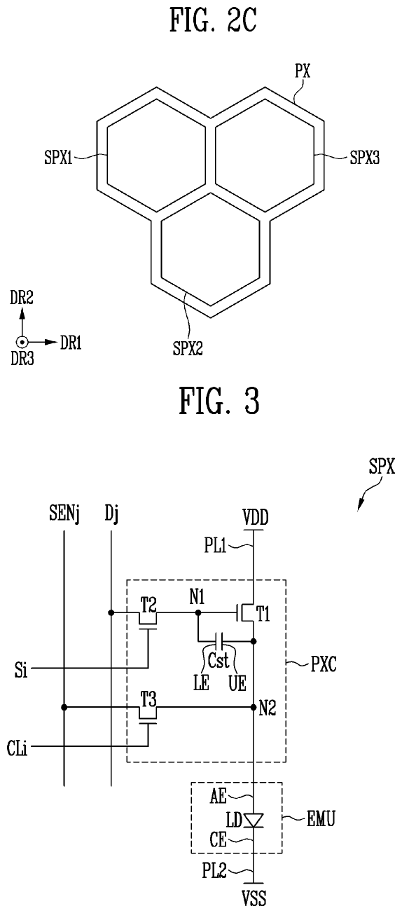

FIG. 1 is a schematic plan view illustrating an embodiment of a display device in accordance with the disclosure. FIGS. 2A to 2C are plan views illustrating embodiments of a pixel shown in FIG. 1.

Referring to FIG. 1, the display device DD is a device which displays a moving image or a still image, and may be used as a display screen of not only portable electronic devices such as a mobile phone, a smart phone, a tablet personal computer (“PC”), a mobile communication terminal, an electronic notebook, an electronic book, a portable multimedia player (“PMP”), a navigation system, and an ultra-mobile PC, but also various products such as a television, a notebook computer, a monitor, an advertisement board, and Internet of Things (“IoT”) device.

The display device DD may be formed in a quadrangular, e.g., rectangular plane having long sides in a first direction DR1 and short sides in a second direction DR2 intersecting the first direction DR1. A corner at which the long side in the first direction DR1 and the short side in the second direction DR2 meet each other may be formed round to have a predetermined curvature or be formed at a right angle. The planar shape of the display device DD is not limited to a quadrangular shape, and the display device DD may be formed in another polygonal shape, a circular shape, or an elliptical shape. The display device DD may be formed flat, but the disclosure is not limited thereto. In an embodiment, the display device DD may include a curved part which is formed at a left/right end and has a constant curvature or a changing curvature, for example. In addition, the display device DD may be formed flexible enough to be warpable, curvable, bendable, foldable or rollable.

The display device DD may further include pixels PX for displaying an image, scan lines extending in the first direction DR1, and data lines extending in the second direction DR2. The pixels PX may be arranged in a matrix form in the first direction DR1 and the second direction DR2.

Referring to FIGS. 1 and 2A to 2C, each of the pixels PX may include a plurality of sub-pixels SPX1, SPX2, and SPX3. In FIGS. 2A to 2C, it is exemplified that each of the pixels PX includes three sub-pixels SPX1, SPX2, and SPX3, i.e., a first sub-pixel SPX1, a second sub-pixel SPX2, and a third sub-pixel SPX3. However, the embodiment of the disclosure is not limited thereto. In FIGS. 2A to 2C, it is exemplified that each of the pixels PX includes a first sub-pixel SPX1, a second sub-pixel SPX2, and a third sub-pixel SPX3. However, the embodiment of the disclosure is not limited thereto.

The first sub-pixel SPX1, the second sub-pixel SPX2, and the third sub-pixel SPX3 may be connected to any one data line among the data lines and at least one scan line among the scan lines.

Referring to FIG. 2A, each of the first sub-pixel SPX1, the second sub-pixel SPX2, and the third sub-pixel SPX3 may have a quadrangular, e.g., rectangular, square or rhombic planar shape. In an embodiment, each of the first sub-pixel SPX1, the second sub-pixel SPX2, and the third sub-pixel SPX3 may have a rectangular planar shape having short sides in the first direction DR1 and long sides in the second direction DR2, for example. In an alternative embodiment, each of the first sub-pixel SPX1, the second sub-pixel SPX2, and the third sub-pixel SPX3 may have a square or rhombic planar shape including sides having the same length in the first direction DR1 and the second direction DR2. The first sub-pixel SPX1, the second sub-pixel SPX2, and the third sub-pixel SPX3 may be arranged in the first direction DR1. In an embodiment, areas of the first to third sub-pixels SPX1 to SPX3 may be the substantially same, but the disclosure is not limited thereto. In an embodiment, the area of at least one of the first to third sub-pixels SPX1 to SPX3 may be different from the area of another of the first to third sub-pixels SPX1 to SPX3, for example. In an alternative embodiment, any two of the area of the first sub-pixel SPX1, the area of the second sub-pixel SPX2, and the area of the third sub-pixel SPX3 may be the substantially same, and the other of the area of the first sub-pixel SPX1, the area of the second sub-pixel SPX2, and the area of the third sub-pixel SPX3 may be different from the two of the area of the first sub-pixel SPX1, the area of the second sub-pixel SPX2, and the area of the third sub-pixel SPX3. In an alternative embodiment, the area of the first sub-pixel SPX1, the area of the second sub-pixel SPX2, and the area of the third sub-pixel SPX3 may be different from one another.

Referring to FIG. 2B, the first sub-pixel SPX1 may be arranged with any one of the second sub-pixel SPX2 and the third sub-pixel SPX3 in the first direction DR1, and be arranged with the other of the second sub-pixel SPX2 and the third sub-pixel SPX3 in the second direction DR2. In an embodiment, the first sub-pixel SPX1 may be arranged side by side with the second sub-pixel SPX2 in the first direction DR1, and be arranged with the third sub-pixel SPX3 in the second direction DR2, for example. In an embodiment, the third sub-pixel SPX3 may be disposed in the second direction DR2 from the first sub-pixel SPX1 and the second sub-pixel SPX2. In an embodiment, areas of the first and second sub-pixels SPX1 and SPX2 may be the substantially same, and an area of the third sub-pixel SPX3 may be different from the areas of the first and second sub-pixels SPX1 and SPX2. In an embodiment, the area of the third sub-pixel SPX3 may be wider than the areas of the first and second sub-pixels SPX1 and SPX2, for example.

Referring to FIG. 2C, each of the first sub-pixel SPX1, the second sub-pixel SPX2, and the third sub-pixel SPX3 may have a hexagonal or regular hexagonal planar shape. In an embodiment, adjacent two surfaces among six surfaces of each of the first to third sub-pixels SPX1 to SPX3 may face one surface of adjacent sub-pixels.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band of about 600 nanometers (nm) to about 750 nm, the green wavelength band may be a wavelength band of about 480 nm to about 560 nm, and the blue wavelength band may be a wavelength band of about 370 nm to about 460 nm. However, the embodiment of the disclosure is not limited thereto.

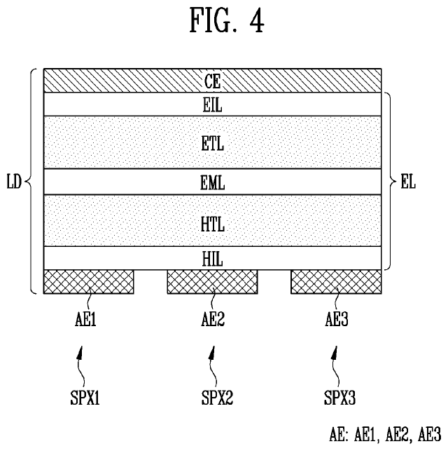

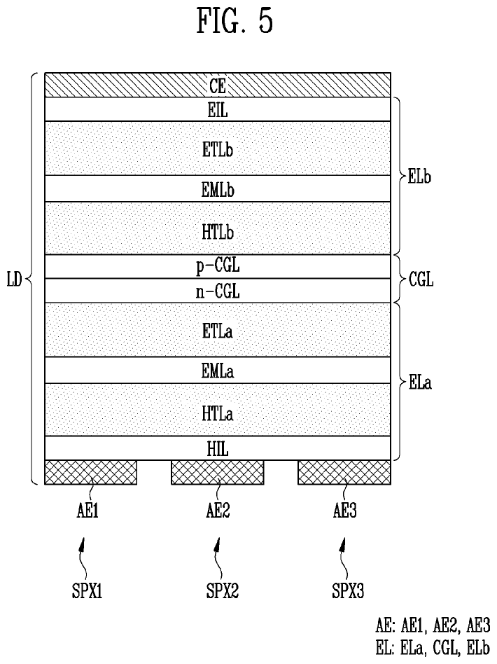

Each of the first sub-pixel SPX1, the second sub-pixel SPX2, and the third sub-pixel SPX3 may include a light-emitting element LD (e.g., a light-emitting element LD shown in FIGS. 4 and 5) emitting light, and the light-emitting element LD may include an organic light-emitting element having an organic layer.

An area of the first sub-pixel SPX1, an area of the second sub-pixel SPX2, and an area of the third sub-pixel SPX3 may be the substantially same, but the embodiments of the disclosure are not limited thereto. At least one of the area of the first sub-pixel SPX1, the area of the second sub-pixel SPX2, and the area of the third sub-pixel SPX3 may be different from another of the area of the first sub-pixel SPX1, the area of the second sub-pixel SPX2, and the area of the third sub-pixel SPX3. In an alternative embodiment, any two of the area of the first sub-pixel SPX1, the area of the second sub-pixel SPX2, and the area of the third sub-pixel SPX3 may be the substantially same, and the other of the area of the first sub-pixel SPX1, the area of the second sub-pixel SPX2, and the area of the third sub-pixel SPX3 may be different from the two of the area of the first sub-pixel SPX1, the area of the second sub-pixel SPX2, and the area of the third sub-pixel SPX3. In an alternative embodiment, the area of the first sub-pixel SPX1, the area of the second sub-pixel SPX2, and the area of the third sub-pixel SPX3 may be different from one another.

FIG. 3 is a circuit diagram illustrating an embodiment of the sub-pixel included in the pixel shown in FIGS. 2A to 2C.

A sub-pixel SPX shown in FIG. 3 may be any one of the sub-pixels SPX1 to SPX3 shown in FIGS. 2A to 2C, and sub-pixels SPX1 to SPX3 arranged in a display area of each display device DD may be configured substantially identically or similarly to one another.

For convenience of description, a sub-pixel SPX disposed on an ith pixel row (or ith horizontal line) and a jth pixel column will be illustrated in FIG. 3 (i and j are positive integers).

Referring to FIG. 3, the sub-pixel SPX may include a light-emitting unit EMU which generates light with a luminance corresponding to a data signal. Also, the sub-pixel SPX may further include a pixel circuit PXC for driving the light-emitting unit EMU.

The light-emitting unit EMU may include a light-emitting element LD connected between a first power line PL1 supplied with a voltage of a first driving power source VDD (or first power source) and a second power line PL2 supplied with a voltage of a second driving power source VSS (or second power source). In an embodiment, the light-emitting unit EMU may include a light-emitting element LD including a first pixel electrode AE connected to the first driving power source VDD via the pixel circuit PXC and the first power line PL1 and a second pixel electrode CE connected to the second driving power source VSS via the second power line PL2. The first pixel electrode AE may be an anode, and the second pixel electrode CE may be a cathode. The first driving power source VDD and the second driving power source VSS may have different potentials. A potential difference between the first and second driving power sources VDD and VSS may be set equal to or higher than a threshold voltage of the light-emitting element LD during an emission period of a sub-pixel SPX.

When the sub-pixel SPX is disposed on an ith pixel row and a jth pixel column in the display area of the display device DD, the pixel circuit PXC of the sub-pixel SPX may be electrically connected to an ith scan line Si and a jth data line Dj. Also, the pixel circuit PXC may be electrically connected to an ith control line CLi and a jth sensing line SENj.

The above-described pixel circuit PXC may include first to third transistors T1, T2, and T3 and a storage capacitor Cst.

The first transistor T1 is a driving transistor for controlling a driving current applied to the light-emitting element LD, and may be electrically connected between the first driving power source VDD and the light-emitting element LD. Specifically, a first terminal of the first transistor T1 may be electrically connected to the first driving power source VDD through the first power line PL1, a second terminal of the first transistor T1 may be electrically connected to a second node N2, and a gate electrode of the first transistor T1 may be electrically connected to a first node N1. The first transistor T1 may control an amount of driving current applied from the first driving power source VDD to the light-emitting element LD through the second node N2 according to a voltage applied to the first node N1. In an embodiment, the first terminal of the first transistor T1 may be a drain electrode, and the second terminal of the first transistor T1 may be a source electrode. However, the disclosure is not limited thereto. In some embodiments, the first terminal may be the source electrode, and the second terminal may be the drain electrode.

The second transistor T2 is a switching transistor which selects a sub-pixel SPX in response to a scan signal and activates the sub-pixel SPX, and may be electrically connected between a data line Dj (e.g., the jth data line) and the first node N1. A first terminal of the second transistor T2 may be electrically connected to the data line Dj, a second terminal of the second transistor T2 may be electrically connected to the first node N1 (or the gate electrode of the first transistor T1), and a gate electrode of the second transistor T2 may be electrically connected to a scan line Si (or the ith scan line). The first terminal and the second terminal of the second transistor T2 are different terminals from each other. In an embodiment, when the first terminal is a drain electrode, the second terminal may be a source electrode, for example.

The second transistor T2 may be turned on when a scan signal having a gate-on voltage (e.g., a relatively high level voltage) is supplied from the scan line Si, to electrically connect the data line Dj and the first node N1 to each other. The first node N1 is a point at which the second terminal of the second transistor T2 and the gate electrode of the first transistor T1 are connected to each other, and the second transistor T2 may transfer a data signal to the gate electrode of the first transistor T1.

The third transistor T3 may electrically connect the first transistor T1 to a sensing line SENj (e.g., the jth sensing line), to acquire a sensing signal through the sensing line SENj, and detect a characteristic of the sub-pixel SPX, including a threshold voltage of the first transistor T1, or the like, by the sensing signal. Information on the characteristic of the sub-pixel SPX may be used to convert image data such that a characteristic deviation between sub-pixels SPX may be compensated. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to a control line CLi (e.g., the ith control line). The first terminal may be a drain electrode, and the second terminal may be a source electrode.

The third transistor T3 is an initialization transistor capable of initializing the second node N2, and may be turned on when a sensing control signal is supplied from the control line CLi, to transfer a voltage of an initialization power source to the second node N2. Accordingly, the storage capacitor Cst electrically connected to the second node N2 may be initialized.

The storage capacitor Cst may include a lower electrode LE (or first storage electrode) and an upper electrode UE (or second storage electrode). The lower electrode LE may be electrically connected to the first node N1, and the upper electrode UE may be electrically connected to the second node N2. The storage capacitor Cst is charged with a data voltage corresponding to a data signal supplied to the first node N1 during one frame period. Accordingly, the storage capacitor Cst may store a voltage corresponding to a difference between a voltage of the gate electrode of the first transistor T1 and a voltage of the second node N2.

Although an embodiment in which the first to third transistors T1 to T3 are all N-type transistors has been disclosed in FIG. 3, the disclosure is not limited thereto. In an embodiment, at least one of the above-described first to third transistors T1 to T3 may be replaced with a P-type transistor, for example. The structure of the pixel circuit PXC may be variously modified and embodied.

FIG. 4 is a cross-sectional view illustrating an embodiment of the light-emitting element shown in FIG. 3.

Referring to FIG. 4, a light-emitting element LD may include a first pixel electrode AE, an organic light-emitting part EL, and a second pixel electrode CE, which are sequentially stacked.

In an embodiment, the first pixel electrode AE may be patterned to correspond to the first to third sub-pixels SPX1 to SPX3. In an embodiment, the first pixel electrode AE may include first to third sub-pixel electrodes AE1 to AE3 respectively corresponding to the first to third sub-pixels SPX1 to SPX3. The first sub-pixel electrode AE1 may be a pixel electrode corresponding to the first sub-pixel SPX1, the second sub-pixel electrode AE2 may be a pixel electrode corresponding to the second sub-pixel SPX2, and the third sub-pixel electrode AE3 may be a pixel electrode corresponding to the third sub-pixel SPX3.

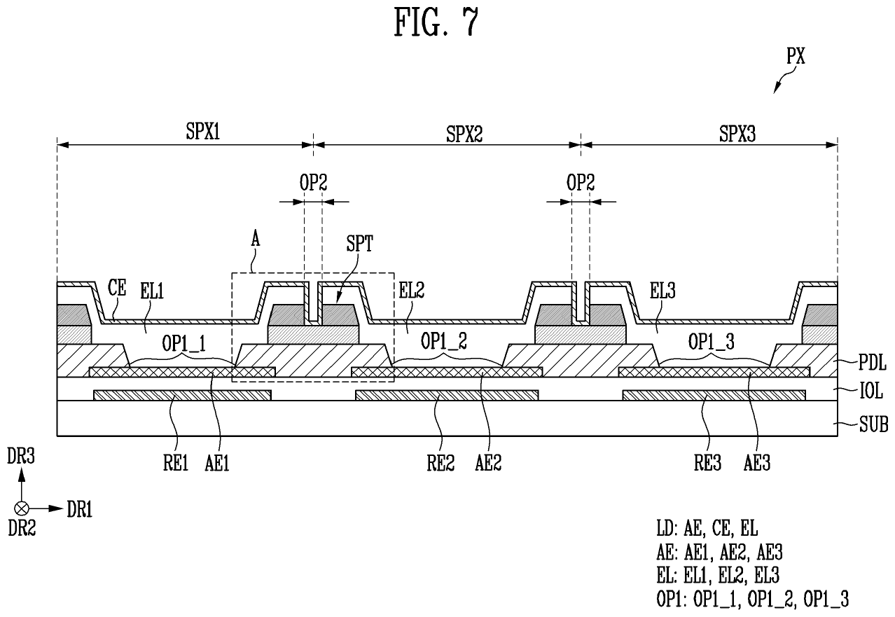

In an embodiment, the organic light-emitting part EL may be provided on the first to third sub-pixel electrodes AE1 to AE3 patterned to respectively correspond to the first to third sub-pixels SPX1 to SPX3. The organic light-emitting part EL may include a plurality of light generation layers, and at least some of the plurality of light generation layers constituting the organic light-emitting part EL may be unitary with the first to third sub-pixels SPX1 to SPX3 or be separated from the first to third sub-pixels SPX1 to SPX3. In an embodiment, the organic light-emitting part EL may include a plurality of light generation layers interrupted by a separator (e.g., a separator SPT shown in FIG. 7 or a separator SPT′ shown in FIG. 10) disposed between the first to third sub-pixels SPX1 to SPX3.

The organic light-emitting part EL may have a multi-layer thin film structure including a plurality of light generation layers. The organic light-emitting part EL may include a hole injection layer HIL, a hole transport layer HTL, an organic light-emitting layer EML, an electron transport layer ETL, and an electron injection layer EIL, which are sequentially stacked.

The hole injection layer HIL may be an organic layer disposed between the first pixel electrode AE and the hole transport layer HTL to allow holes to be smoothly injected into the organic light-emitting layer EML from the first pixel electrode AE. The hole transport layer HTL may be disposed between the hole injection layer HIL and the organic light-emitting layer EML, to perform a function of receiving holes provided from the first to third sub-pixel electrodes AE1 to AE3 and transporting the holes to the organic light-emitting layer EML.

The electron injection layer EIL may be disposed between the electron transport layer ETL and the second pixel electrode CE. The electron transport layer ETL may be disposed on the organic light-emitting layer EML, to perform a function of receiving electrons provided from the second pixel electrode CE and transporting the electrons to the organic light-emitting layer EML.

The organic light-emitting layer EML is an area in which light is generated by a recombination of electrons and holes, which are supplied from the first pixel electrode AE and the second pixel electrode CE. The organic light-emitting layer EML may include an organic light-emitting material such as a relatively high molecular organic material or a relatively low molecular organic material, which emits light of a predetermined color. In an embodiment, the organic light-emitting layer EML may be provided with an organic material emitting blue light, for example. However, the disclosure is not limited thereto. In an embodiment, the organic light-emitting layer EML may be provided with an organic material emitting red or green light, or be provided with an inorganic material or a quantum dot.

In an embodiment, the second pixel electrode CE may be integrally provided. The second pixel electrode CE may be disposed on the organic light-emitting part EL. The second pixel electrode CE may be unitary in light-emitting elements.

FIG. 5 is a cross-sectional view illustrating another embodiment of the light-emitting element shown in FIG. 3.

Referring to FIG. 5, a light-emitting element LD may include a first pixel electrode AE, an organic light-emitting part EL, and a second pixel electrode CE.

The organic light-emitting part EL may include a plurality of light generation layers. In an embodiment, the organic light-emitting part EL may include a first organic light-emitting part ELa, a charge generation layer CGL, and a second organic light-emitting part ELb. The first pixel electrode AE, the first organic light-emitting part ELa, the charge generation layer CGL, the second organic light-emitting part ELb, and the second pixel electrode CE may be sequentially stacked.

The first organic light-emitting part ELa may be provided in a structure in which a hole injection layer HIL, a first hole transport layer HTLa, a first organic light-emitting layer EMLa, and a first electron transport layer ETLa are sequentially stacked. The second organic light-emitting part ELb may be provided in a structure in which the second hole transport layer HTLb, a second organic light-emitting layer EMLb, a second electron transport layer ETLb, and an electron injection layer EIL are sequentially stacked.

In an embodiment, a buffer layer (not shown) may be disposed on the first organic light-emitting layer EMLa and the second organic light-emitting layer EMLb. The buffer layer may include an electron transport compound.

The charge generation layer CGL may perform a function of supplying charges to the first organic light-emitting part ELa and the second organic light-emitting part ELb. The charge generation layer CGL may include an n-type charge generation layer n-CGL for supplying charges to the first organic light-emitting part ELa and a p-type charge generation layer p-CGL for supplying holes to the second organic light-emitting part ELb. The n-type charge generation layer n-CGL may include a metal material as a dopant.

In FIG. 5, it has been illustrated that the light-emitting element LD is provided such that two organic light-emitting parts ELa and ELb of the light-emitting element LD are stacked. However, the disclosure is not limited thereto. In an embodiment, the light-emitting element LD may be provided such that three or four or more organic light-emitting parts are stacked in the light-emitting element LD, for example.

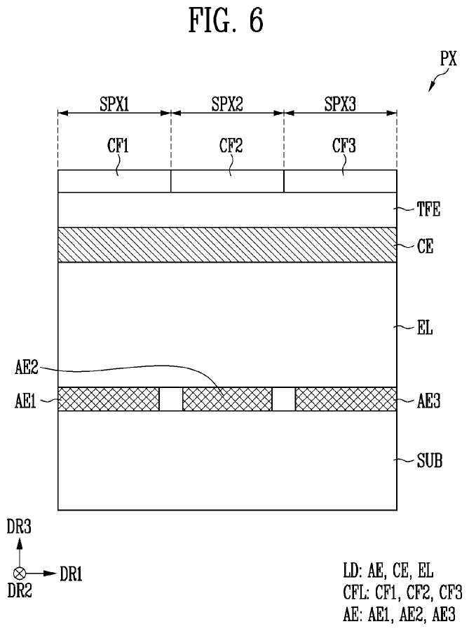

FIG. 6 is a cross-sectional view illustrating a stacked structure of a pixel including the light-emitting element shown in FIG. 3.

Referring to FIG. 6, the pixel PX may include a substrate SUB, a light-emitting element LD, an encapsulation layer TFE, and a color filter layer CFL.

The substrate SUB may include a silicon substrate, but the disclosure is not limited thereto. In an embodiment, the substrate SUB may be a rigid substrate or a flexible substrate, for example. The rigid substrate may be, e.g., a glass substrate, a quartz substrate, a glass ceramic substrate, and a crystalline glass substrate. The light-emitting element LD may be disposed on the substrate SUB. A pixel circuit layer (not shown) may be disposed between the substrate SUB and the light-emitting element LD. The pixel circuit layer may include various driving elements, various lines, or the like, which are used to drive the light-emitting element LD. In an embodiment, the pixel circuit layer may be configured with various components such as transistors (e.g., the first to third transistors T1 to T3 shown in FIG. 3), a storage capacitor (e.g., the storage capacitor Cst shown in FIG. 3), a scan line, and a data line, for example, but the disclosure is not limited thereto.

The light-emitting element LD (or an organic light-emitting element layer) may be disposed on the substrate SUB. The light-emitting element LD may include first pixel electrodes AE, an organic light-emitting part EL, and a second pixel electrode CE.

The first pixel electrodes AE may be patterned with respect to first to third sub-pixels SPX1 to SPX3. Since the first pixel electrodes AE supply holes to the organic light-emitting part EL, the first pixel electrodes AE may include or consist of a transparent conductive material having a relatively high work function.

The first pixel electrodes AE may include or consist of a transparent conductive material such as tin oxide (“TO”), zinc oxide (ZnO), indium tin oxide (“ITO”), indium zinc oxide (“IZO”), or indium zinc tin oxide (“ITZO”), but the disclosure is not limited thereto.

The organic light-emitting part EL may be disposed between the first pixel electrodes AE and the second pixel electrode CE. The organic light-emitting part EL may be an area in which light is emitted by recombination of electrons and holes, which are supplied from the first pixel electrodes AE and the second pixel electrode CE.

The organic light-emitting part EL may be a white light-emitting layer from which white light is emitted. The white light emitted from the organic light-emitting part EL may be converted into light of any one of red, green, and blue by the color filter layer CFL. A design inside the organic light-emitting part EL may also be changed according to a color of light to be implemented. In an embodiment, when the corresponding pixel is a green pixel, the organic light-emitting part EL may include a green light-emitting layer, thereby emitting green light, for example. When the corresponding pixel is a red pixel, the organic light-emitting part EL may include a red light-emitting layer, thereby emitting red light. When the corresponding pixel is a blue pixel, the organic light-emitting part EL may include a blue light-emitting layer, thereby emitting blue light. The color filter layer may not be disposed above the light-emitting element LD.

The second pixel electrode CE may be disposed on the organic light-emitting part EL. The second pixel electrode CE may be formed as one layer throughout the entirety of the surface of the substrate SUB. Second pixel electrodes CE of the respective first to third sub-pixels SPX1 to SPX3 may be connected to each other to be unitary. Since the second pixel electrode CE supplies electrons to the organic light-emitting part EL, the second pixel electrode CE may include a conductive material having a relatively low work function. In an embodiment, the second pixel electrode CE may include or consist of a transparent conductive material such as TO, Zinc Oxide (ZnO), ITO, IZO, or ITZO, or an ytterbium alloy, for example. Also, the second pixel electrode CE may include or consist of a metal material such as silver (Ag), copper (Cu), or a magnesium-silver (Mg—Ag) alloy, or a metal material having a relatively thin thickness, but the disclosure is not limited thereto.

The encapsulation layer TFE may be disposed on the second pixel electrode CE. The encapsulation layer TFE may block infiltration of moisture or oxygen, which is introduced from the outside, thereby protecting the light-emitting element LD. The encapsulation layer TFE may be a multi-layer in which an inorganic layer and an organic layer are alternately disposed.

The color filter layer CFL may be disposed on the encapsulation layer TFE. The color filter layer CFL may include first to third color filters CF1 to CF3 to respectively correspond to the first to third sub-pixels SPX1 to SPX3. The color filter layer CFL may convert white light emitted from the organic light-emitting part EL of the light-emitting element LD into light of a predetermined color.

The first color filter CF1 may be disposed in an area corresponding to a first sub-pixel electrode AE1 of the first sub-pixel SPX1. The first color filter CF1 may allow light of a first color to be selectively transmitted therethrough. In an embodiment, the first color filter CF1 may include a color filter material of the first color, which allows light of the first color to be transmitted therethrough and blocks lights of second and third colors, for example.

The second color filter CF2 may be disposed in an area corresponding to a second sub-pixel electrode AE2 of the second sub-pixel SPX2. In an embodiment, the second color filter CF2 may include a color filter material of the second color, which allows light of the second color to be transmitted therethrough and blocks lights of the first and third colors, for example.

The third color filter CF3 may be disposed in an area corresponding to a third sub-pixel electrode AE3 of the third sub-pixel SPX3. In an embodiment, the third color filter CF3 may include a color filter material of the third color, which allows light of the third color to be transmitted therethrough and blocks lights of the first and second colors, for example.

In an embodiment, when the first sub-pixel SPX1 is a red sub-pixel, the first color filter CF1 may include a red color filter. When the second sub-pixel SPX2 is a green sub-pixel, the second color filter CF2 may include a green color filter. When the third sub-pixel SPX3 is a blue sub-pixel, the third color filter CF3 may include a blue color filter.

FIG. 7 is a cross-sectional view illustrating an embodiment of the pixel shown in FIG. 6.

Referring to FIG. 7, a pixel PX may include a substrate SUB, an inorganic layer IOL, reflective electrodes RE1 to RE3, first pixel electrodes AE, an organic light-emitting part EL, a second pixel electrode CE, a pixel defining layer PDL, and a separator SPT.

The reflective electrodes RE1 to RE3 may be disposed on the substrate SUB. The reflective electrodes RE1 to RE3 may include first to third reflective electrodes RE1 to RE3. The first to third reflective electrodes RE1 to RE3 may be disposed on the substrate SUB to be spaced apart from each other in the first direction DR1.

The first to third reflective electrodes RE1 to RE3 may be disposed under first to third sub-pixel electrodes AE1 to AE3, respectively. The reflective electrodes RE1 to RE3 may be disposed under the first to third sub-pixel electrodes AE1 to AE3 to reflect light emitted from the organic light-emitting part EL toward the second pixel electrode CE. The first to third reflective electrodes RE1 to RE3 may include a metal material having excellent reflectivity. In an embodiment, the first to third reflective electrodes RE1 to RE3 may include or consist of a material such as aluminum (Al), titanium (Ti), silver (Ag), silver alloy (Ag alloy), copper (Cu), or magnesium-silver alloy (Mg—Ag), for example, but the disclosure is not limited thereto.

The first reflective electrode RE1 may be disposed under a first sub-pixel electrode AE1 of a first sub-pixel SPX1. The second reflective electrode RE2 may be disposed under a second sub-pixel electrode AE2 of a second sub-pixel SPX2. The third reflective electrode RE3 may be disposed under a third sub-pixel electrode AE3 of a third sub-pixel SPX3.

In FIG. 7, it is illustrated that the first to third reflective electrodes RE1 to RE3 are disposed in the same layer on the substrate SUB. However, the disclosure is not limited thereto. In an embodiment, the first to third reflective electrodes RE1 to RE3 may be disposed in different layers from each other. In an embodiment, each of the first to third reflective electrodes RE1 to RE3 may be disposed at a position for implementing a micro cavity effect, for example. Distances between organic light-emitting parts EL1 to EL3 and the first to third reflective electrodes RE1 to RE3 are adjusted, thereby improving the light emission efficiency of the first to third sub-pixels SPX1 to SPX3.

The inorganic layer IOL may be entirely disposed on the substrate SUB and the reflective electrodes RE1 to RE3. The inorganic layer IOL may be disposed between the substrate SUB and a light-emitting element LD. The inorganic layer IOL may serve as a cavity control layer which amplifies light emitted from the organic light-emitting part EL and improves light emission efficiency. The inorganic layer IOL may be disposed between the reflective electrodes RE1 to RE3 and the first to third sub-pixel electrodes AE1 to AE3 to be formed in a structure for implementing micro cavities. In FIG. 7, it is illustrated that the inorganic layer IOL has a uniform thickness on the substrate SUB. However, the disclosure is not limited thereto. In an embodiment, the inorganic layer IOL may have different thicknesses with respect to the first to third sub-pixels SPX1 to SPX3 such that each of the first to third sub-pixels SPX1 to SPX3 implement a micro cavity corresponding to light emitted in the corresponding sub-pixel, for example.

The first to third sub-pixel electrodes AE1 to AE3 may be disposed on the inorganic layer IOL. The first to third sub-pixel electrodes AE1 to AE3 may be spaced apart from each other in the first direction DR1. Each of the first to third sub-pixel electrodes AE1 to AE3 may be electrically connected to a pixel circuit layer (not shown) formed on the substrate SUB through a contact hole (not shown).

The pixel defining layer PDL may be disposed over the first to third sub-pixel electrodes AE1 to AE3 to define a position at which the organic light-emitting part EL is arranged. The pixel defining layer PDL may partition the first to third sub-pixels SPX1 to SPX3. First openings OP1 for exposing at least one area of the first to third sub-pixel electrodes AE1 to AE3 may be defined in the pixel defining layer PDL. The first openings OP1 may overlap with emission areas of the respective first to third sub-pixels SPX1 to SPX3.

The first openings OP1 may include a (1_1)^{th} opening OP1_1, a (1_2)^{th} opening OP1_2, and a (1_3)^{th} opening OP1_3. The first sub-pixel electrode AE1 of the first sub-pixel SPX1 may be exposed through the (1_1)^{th} opening OP1_1. The second sub-pixel electrode AE2 of the second sub-pixel SPX2 may be exposed through the (1_2)^{th} opening OP1_2. The third sub-pixel electrode AE3 of the third sub-pixel SPX3 may be exposed through the (1_3)^{th} opening OP1_3. The organic light-emitting part EL may be disposed on the first pixel electrode AE exposed through the first openings OP1.

The pixel defining layer PDL may include an inorganic material. In an embodiment, the pixel defining layer PDL may include at least one of silicon oxide (SiOₓ) and silicon nitride (SiNₓ), for example. In some embodiments, the pixel defining layer PDL may have a multi-layer structure in which a layer including silicon oxide (SiOₓ) and a layer including silicon nitride (SiNₓ) are stacked. However, the disclosure is not limited thereto. In other embodiments, the pixel defining layer PDL may include an organic material. In an embodiment, the pixel defining layer PDL may include at least one of acrylic resin, epoxy resin, phenolic resin, polyamide resin, and polyimide resin.

The separator SPT may be disposed on the pixel defining layer PDL. A second opening OP2 may be defined in the separator SPT. The second opening OP2 may be a step difference defined in a top surface of the separator SPT. In the disclosure, the separator SPT is a structure which physically separates a plurality of light generation layers of the light-emitting element LD, and be designated as the term “separator” and other terms.

The second opening OP2 may separate the organic light-emitting part EL disposed on the pixel defining layer PDL into first to third light-emitting parts EL1 to EL3.

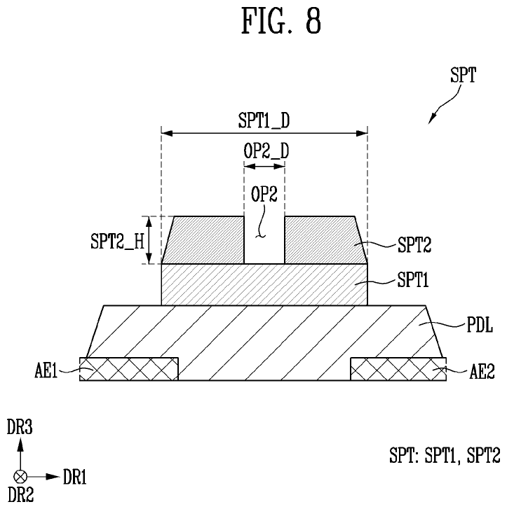

A structure of the separator SPT will be described in detail with reference to FIG. 8.

In an embodiment, the organic light-emitting part EL may be disposed on the first to third sub-pixel electrodes AE1 to AE3 exposed through the first openings OP1 of the pixel defining layer PDL.

In an embodiment, the organic light-emitting part EL may include a plurality of light generation layers. In an embodiment, the organic light-emitting part EL may be separated into the first light-emitting part EL1, the second light-emitting part EL2, and the third light-emitting part EL3 by the separator SPT. In another embodiment, some of the plurality of light generation layers constituting the organic light-emitting part EL may continuously extend from the first sub-pixel SPX1 to the third sub-pixel SPX3, but the others of the plurality of light generation layers may be separated by the separator SPT. In an embodiment, a hole injection layer (e.g., the hole injection layer HIL shown in FIGS. 4 and 5) and/or a charge generation layer (e.g., the charge generation layer CGL shown in FIG. 5) among the plurality of light generation layers constituting the organic light-emitting part EL may be separated by the separator SPT.

The organic light-emitting part EL may be disposed in an area surrounded by the separator SPT. The organic light-emitting part EL may include the first light-emitting part EL1 for forming the first sub-pixel SPX1, the second light-emitting part EL2 for forming the second sub-pixel SPX2, and the third light-emitting part EL3 for forming the third sub-pixel SPX3.

The separator SPT may be disposed in boundary areas between adjacent light-emitting parts EL1 to EL3 (or the first to third sub-pixels SPX1 to SPX3).

In an embodiment, the second pixel electrode CE may be disposed on the organic light-emitting part EL. The second pixel electrode CE may be disposed (or formed) as one layer throughout the entirety of the surface of the first to third light-emitting parts EL1 to EL3. The second pixel electrode CE may be disposed according to a profile of the first to third light-emitting parts EL1 to EL3 and the separator SPT. At least a portion of the second pixel electrode CE may be disposed in the second opening OP2 of the separator SPT. In an embodiment, when all the plurality of light generation layers constituting the organic light-emitting part EL are separated by the separator SPT, the second pixel electrode CE disposed on the second opening OP2 may contact at least a portion of the separator SPT.

In the display device in the embodiment of the disclosure, the organic light-emitting part EL commonly disposed in the first to third sub-pixels SPX1 to SPX3 may be separated into the first to third light-emitting parts EL1 to EL3 respectively corresponding to the sub-pixels through the separator SPT. Accordingly, a lateral leakage phenomenon between adjacent sub-pixels, which is caused by the organic light-emitting part EL commonly disposed in the first to third sub-pixels SPX1 to SPX3, may be reduced or prevented, thereby preventing a decrease of the luminance or color purity of the display device.

FIG. 8 is an enlarged view illustrating an embodiment of area A shown in FIG. 7.

Referring to FIGS. 7 and 8, a separator SPT may be disposed on the pixel defining layer PDL.

In an embodiment, the separator SPT may include a first layer SPT1 and a second layer SPT2. In an embodiment, the first layer SPT1 may be disposed on a top surface of the pixel defining layer PDL. The second layer SPT2 may be disposed on the first layer SPT1. A second opening OP2 exposing one area of the first layer SPT1 may be defined in the second layer SPT2. The second opening OP2 may penetrate the second layer SPT2 in a third direction DR3. The one area of the first layer SPT1 may be exposed through the second opening OP2.

Referring to FIGS. 7 and 8, the separator SPT may be disposed between the first to third sub-pixels SPX1 to SPX3, to cut the organic light-emitting part EL in the third direction DR3 through a step difference formed by the second opening OP2. The separator SPT may physically separate the organic light-emitting part EL into the first to third light-emitting parts EL1 to EL3, and the first to third light-emitting parts EL1 to EL3 are physically separated from each other, so that movement of charges/holes between the first to third light-emitting parts EL1 to EL3 may be blocked.

In an embodiment, the separator SPT may have a width SPT1_D. The width SPT1_D may be about 1000 nm.

In an embodiment, a height SPT2_H of the second layer SPT2 (or a depth or height of the second opening OP2) may have a height within a range for cutting the organic light-emitting part EL. In an embodiment, the height SPT2_H of the second layer SPT2 may become higher as a height of the organic light-emitting part EL becomes higher. That is, the height SPT2_H of the second layer SPT2 may be in proportion to the height of the organic light-emitting part EL.

In an embodiment, a width OP2_D of the second opening OP2 may be determined by considering the height of the organic light-emitting part EL and/or a thickness of the second pixel electrode CE. As the width OP2_D of the second opening OP2 becomes wider, the second pixel electrode CE is not cut and may be disposed on the second opening OP2. As the width OP2_D of the second opening OP2 becomes narrower, the second pixel electrode CE may be cut together with the organic light-emitting part EL. Therefore, the width OP2_D of the second opening OP2 may be determined within a range in which the second pixel electrode CE is not cut while the organic light-emitting part EL is cut. In an embodiment, the width OP2_D of the second opening OP2 may be about 135 nm or less.

In an embodiment, the first layer SPT1 and the second layer SPT2 may include different materials from each other.

In an embodiment, the first layer SPT1 may include a metal material. In an embodiment, the first layer SPT1 may include at least one of various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), or the like, but the disclosure is not limited thereto. The first layer SPT1 may include at least one conductive material among an alloy including the aforementioned metal material, a conductive oxide such as ITO, IZO, ITZO, aluminum doped zinc oxide (“AZO”), gallium doped zinc oxide (“GZO”), zinc tin oxide (“ZTO”), or gallium tin oxide (“GTO”), and a conductive polymer such as poly(3,4-ethylenedioxythiophene) (“PEDOT”), but the disclosure is not necessarily limited thereto.

In an embodiment, the second layer SPT2 may include an inorganic material. The second layer SPT2 may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, a plurality of light generation layers constituting the organic light-emitting part EL may be separated by the separator SPT. The plurality of light generation layers may include a hole injection layer (e.g., the hole injection layer HIL shown in FIGS. 4 and 5), a hole transport layer (e.g., the hole transport layer HTL shown in FIG. 4 or the first and second hole transport layers HTLa and HTLb shown in FIG. 5), an organic light-emitting layer (e.g., the organic light-emitting layer EML shown in FIG. 4 or the first and second organic light-emitting layers EMLa and EMLb shown in FIG. 5), an electron transport layer (e.g., the electron transport layer ETL shown in FIG. 4 or the first and second electron transport layers ETLa and ETLb shown in FIG. 5), a charge generation layer (e.g., the charge generation layer CGL shown in FIG. 5), and an electron injection layer (e.g., the electron injection layers EIL shown in FIGS. 4 and 5). In an embodiment, at least one of the hole injection layer, the hole transport layer, the light-emitting layer, the electron transport layer, the charge generation layer, and the electron injection layer may be cut in the second opening OP2 by the separator SPT. The plurality of light generation layers cut by the separator SPT may not be disposed on the first layer SPT1 exposed through the second opening OP2. In an embodiment, the hole injection layer (e.g., the hole injection layer HIL shown in FIGS. 4 and 5) and/or the charge generation layer (e.g., the charge generation layer CGL shown in FIG. 5) among the plurality of light generation layers constituting the organic light-emitting part EL may be separated by the separator SPT, for example. The hole injection layer and the charge generation layer may not be disposed on the first layer SPT1 exposed through the second opening OP2.

The display device in the embodiment of the disclosure may include the first to third light-emitting parts EL1 to EL3 separated from each other with respect to the second opening OP2 through the separator SPT. In addition, the second pixel electrode CE disposed on the organic light-emitting part EL may be in direct contact with the first layer SPT1 on the first layer SPT1 exposed through the second opening OP2 as the organic light-emitting part EL is cut with respect to the second opening OP2. Accordingly, a driving voltage of the first to third sub-pixels SPX1 to SPX3 may be decreased.

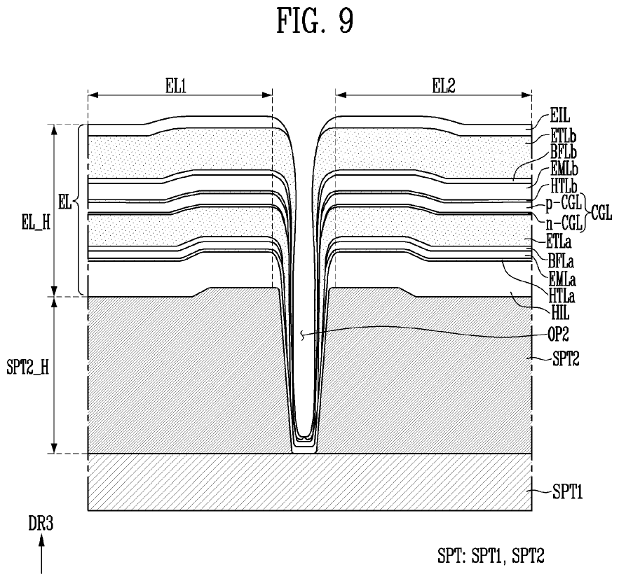

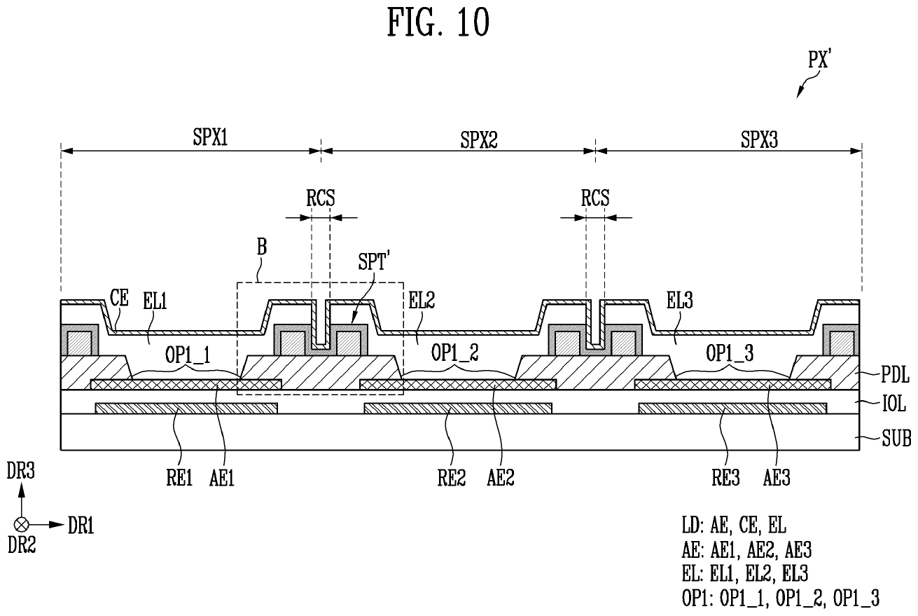

FIG. 9 is a cross-sectional view illustrating some components of the organic light-emitting part disposed on the first layer and the second layer, which are shown in FIG. 8.

Referring to FIG. 9, an organic light-emitting part EL of a light-emitting element (e.g., the light-emitting element LD shown in FIG. 5) may be disposed on the separator SPT.

The organic light-emitting part EL may include a plurality of light generation layers. In an embodiment, the plurality of light generation layers may include a hole injection layer HIL, a first hole transport layer HTLa, a first organic light-emitting layer EMLa, a first buffer layer BFLa, a first electron transport layer ETLa, a charge generation layer CGL, a second hole transport layer HTLb, a second organic light-emitting layer EMLb, a second buffer layer BFLb, a second electron transport layer ETLb, and an electron injection layer EIL.

The hole injection layer HIL, the first hole transport layer HTLa, the first organic light-emitting layer EMLa, the first buffer layer BFLa, the first electron transport layer ETLa, the charge generation layer CGL, the second hole transport layer HTLb, the second organic light-emitting layer EMLb, the second buffer layer BFLb, the second electron transport layer ETLb, and the electron injection layer EIL may be sequentially disposed on the separator SPT in the third direction DR3.

The organic light-emitting part EL may be physically separated into a first light-emitting part EL1 and a second light-emitting part EL2 by the second opening OP2 of the separator SPT. In an embodiment, at least one of the plurality of light

generation layer constituting the organic light-emitting part EL may be physically separated by the second opening OP2. The plurality of light generation layers may be separated in the second opening OP2. In an embodiment, the hole injection layer HIL and the charge generation layer CGL may be physically separated by the second opening OP2.

In an embodiment, the other light generation layers except the hole injection layer HIL and the charge generation layer CGL may extend from a first sub-pixel (e.g., the first sub-pixel SPX1 shown in FIG. 7) to a third sub-pixel (e.g., the third sub-pixel SPX3 shown in FIG. 7) to be integrally disposed. In another embodiment, the other light generation layers including the hole injection layer HIL and the charge generation layer CGL may also be physically separated by the second opening OP2.

In an embodiment, as a thickness EL_H of the organic light-emitting part EL becomes thicker, the height SPT2_H of the second opening OP2 may become higher. In an embodiment, when the thickness EL_H of the organic light-emitting part EL is about 700 nm to about 800 nm, the height SPT2_H of the second opening OP2 may be about 300 nm to about 400 nm.

FIG. 10 is a cross-sectional view illustrating an embodiment of the pixel shown in FIG. 6.

Descriptions of the other components except a separator SPT′, which are identical or correspond to those shown in FIG. 7, will be omitted.

Referring to FIG. 10, a pixel PX′ may include a substrate SUB, an inorganic layer IOL, reflective electrodes RE1 to RE3, first to third sub-pixel electrodes AE1 to AE3, an organic light-emitting part EL, a second pixel electrode CE, a pixel defining layer PDL, and a separator SPT′.

The separator SPT′ may be disposed on the pixel defining layer PDL. A recess RCS may be defined in the separator SPT′. The recess RCS may be a step difference (or groove part) defined in a top surface of the separator SPT′.

The recess RCS may physically separate the organic light-emitting part EL disposed on the pixel defining layer PDL into first to third light-emitting parts EL1 to EL3.

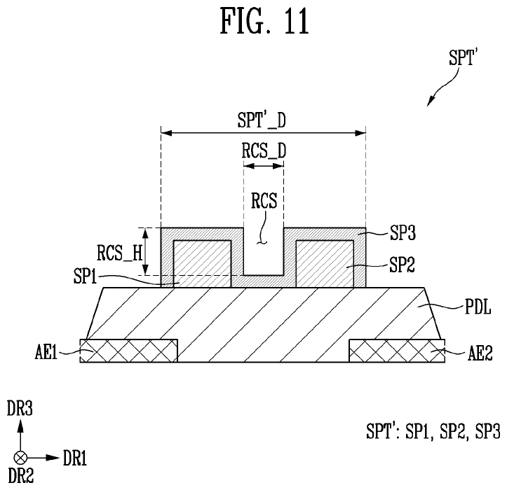

A structure of the separator SPT′ will be described in detail with reference to FIG. 11.

In an embodiment, the organic light-emitting part EL may include a plurality of light generation layers. In an embodiment, the organic light-emitting part EL may be separated into the first light-emitting part EL1, the second light-emitting part EL2, and the third light-emitting part EL3 by the separator SPT′. In another embodiment, some of the plurality of light generation layers constituting the organic light-emitting part EL may continuously extend from a first sub-pixel SPX1 to a third sub-pixel SPX3, but the others of the plurality of light generation layers constituting the organic light-emitting part EL may be separated by the separator SPT′. In an embodiment, a hole injection layer (e.g., the hole injection layer HIL shown in FIG. 4) and/or a charge generation layer (e.g., the charge generation layer CGL shown in FIG. 5) among the plurality of light generation layers constituting the organic light-emitting part EL may be separated by the separator SPT′, for example.

The organic light-emitting part EL may be disposed in an area surrounded by the separator SPT′. The organic light-emitting part EL may include the first light-emitting part EL1 for forming the first sub-pixel SPX1, the second light-emitting part EL2 for forming the second sub-pixel SPX2, and the third light-emitting part EL3 for forming the third sub-pixel SPX3.

The separator SPT′ may be disposed in boundary areas between adjacent light-emitting parts EL1 to EL3 (or the first to third sub-pixels SPX1 to SPX3).

The second pixel electrode CE may be disposed on the organic light-emitting part EL. The second pixel electrode CE may be disposed (or formed) as one layer throughout the entirety of the surface of the first to third light-emitting parts EL1 to EL3. The second pixel electrode CE may be disposed according to a profile of the first to third light-emitting parts EL1 to EL3 and the separator SPT′. At least a portion of the second pixel electrode CE may be disposed in the recess RCS of the separator SPT′. In an embodiment, when all the plurality of light generation layers constituting the organic light-emitting part EL are separated by the separator SPT′, the second pixel electrode CE disposed on the recess RCS may contact at least a portion of the separator SPT′.

In the display device in the embodiment of the disclosure, the organic light-emitting part EL commonly disposed in the first to third sub-pixels SPX1 to SPX3 may be separated into the first to third light-emitting parts EL1 to EL3 respectively corresponding to the sub-pixels, through the separator SPT′. Accordingly, a lateral leakage phenomenon between adjacent sub-pixels, which is caused by the organic light-emitting part commonly disposed in the first to third sub-pixels SPX1 to SPX3, may be reduced or prevented, thereby preventing deterioration of the luminance or color purity of the display device.

FIG. 11 is an enlarged view illustrating an embodiment of area B shown in FIG. 10.

Referring to FIG. 11, a separator SPT′ may be disposed on the pixel defining layer PDL.

In an embodiment, the separator SPT′ may include a first pattern SP1, a second pattern SP2, and a first film SP3.

In an embodiment, the first pattern SP1 and the second pattern SP2 may be disposed on the top surface of the pixel defining layer PDL to be spaced apart from each other in the first direction DR1. In an embodiment, a cross-sectional shape of the first pattern SP1 and the second pattern SP2 may be a quadrangular shape. However, the disclosure is not limited thereto, and the cross-sectional shape of the first pattern SP1 and the second pattern SP2 may be a polygonal shape other than the quadrangular shape, e.g. a triangular shape. In an embodiment, the first pattern SP1 and the second pattern SP2 may have the same shape, but the disclosure is not limited thereto. In an embodiment, a separation distance between the first pattern SP1 and the second pattern SP2 may be about 135 nm or more. However, the disclosure is not limited thereto, and the separation distance between the first pattern SP1 and the second pattern SP2 may be set to a separation distance at which the plurality of light generation layers constituting the organic light-emitting part EL may be separated by the recess RCS.

In an embodiment, the recess RCS may be defined by a separation space of the first pattern SP1 and the second pattern SP2.

In an embodiment, the first film SP3 may cover the first pattern SP1, the second pattern SP2, and the recess RCS. In an embodiment, the first film SP3 may integrally cover the first pattern SP1 and the second pattern SP2. The first film SP3 may have a surface profile corresponding to the shape of the first pattern SP1, the second pattern SP2, and the recess RCS. In an embodiment, the first film SP3 may include a first part covering the first pattern SP1, a second part covering the second pattern SP2, and a third part covering the pixel defining layer PDL exposed between the first pattern SP1 and the second pattern SP2.

In an embodiment, the separator SPT′ may cut the organic light-emitting part (e.g., the organic light-emitting part EL shown in FIG. 10) in the third direction DR3 through the recess RCS defined between the first pattern SP1 and the second pattern SP2. The separator SPT′ may physically separate the organic light-emitting part EL into first to third light-emitting parts EL1 to EL3. As the first to third light-emitting parts EL1 to EL3 are physically separated from each other, movement of charges/holes is blocked, thereby maintaining an electrically short-circuit state.

In an embodiment, the separator SPT′ may have a width SPT′_D. The width SPT′_D may be about 1000 nm.

In an embodiment, a height RCS_H of the recess RCS may have a height within a range for cutting the organic light-emitting part EL. In an embodiment, the height RCS_H of the recess RCS may become higher as a height of the organic light-emitting part EL in the third direction DR3 becomes higher. In an embodiment, when the height of the organic light-emitting part EL is about 700 nm to about 800 nm, the height RCS_H of the recess RCS may be about 300 nm to about 400 nm.

In an embodiment, a width RCS_D of the recess RCS may be determined by considering the height of the organic light-emitting part EL and/or a thickness of the second pixel electrode CE. As the width RCS_D of the recess RCS becomes wider, the second pixel electrode CE is not cut and may be disposed on the recess RCS. As the width RCS_D of the recess RCS becomes narrower, the second pixel electrode CE may be cut together with the organic light-emitting part EL. Therefore, the width RCS_D of the recess RCS may be determined within a range in which the second pixel electrode CE is not cut while the organic light-emitting part EL is cut. In an embodiment, the width RCS_D of the recess RCS may be about 135 nm or less.

In an embodiment, the first pattern SP1 and the second pattern SP2 may include the same material, and the first film SP3 may include a material different from the material of the first and second patterns SP1 and SP2.

In an embodiment, the first and second patterns SP1 and SP2 may include a metal material. In an embodiment, the first and second patterns SP1 and SP2 may include at least one of various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), or the like, but the disclosure is not limited thereto. The first and second patterns SP1 and SP2 may include at least one conductive material among an alloy including the aforementioned metal material, a conductive oxide such as ITO, IZO, ITZO, AZO, GZO, ZTO, or GTO, and a conductive polymer such as PEDOT, but the disclosure is not necessarily limited thereto.

In an embodiment, the first film SP3 may include an inorganic material. The first film SP3 may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, a plurality of light generation layers constituting the organic light-emitting part EL may be separated by the separator SPT′. The plurality of light generation layers may include a hole injection layer (e.g., the hole injection layer HIL shown in FIGS. 4 and 5), a hole transport layer (e.g., the hole transport layer HTL shown in FIG. 4 or the first and second hole transport layers HTLa and HTLb shown in FIG. 5), an organic light-emitting layer (e.g., the organic light-emitting layer EML shown in FIG. 4 or the first and second organic light-emitting layers EMLa and EMLb shown in FIG. 5), an electron transport layer (e.g., the electron transport layer ETL shown in FIG. 4 or the first and second electron transport layers ETLa and ETLb shown in FIG. 5), a charge generation layer (e.g., the charge generation layer CGL shown in FIG. 5), and an electron injection layer (e.g., the electron injection layers EIL shown in FIGS. 4 and 5). In an embodiment, at least one of the hole injection layer, the hole transport layer, the light-emitting layer, the electron transport layer, the charge generation layer, and the electron injection layer may be cut in the recess RCS by the separator SPT′. The plurality of light generation layers cut by the separator SPT′ may not be disposed on the first film SP3 disposed between the first pattern SP1 and the second pattern SP2. In an embodiment, the hole injection layer (e.g., the hole injection layer HIL shown in FIGS. 4 and 5) and/or the charge generation layer (e.g., the charge generation layer CGL shown in FIG. 5) among the plurality of light generation layers constituting the organic light-emitting part EL may be separated by the separator SPT′, for example. The hole injection layer and the charge generation layer may not be disposed on the first film SP3 disposed between the first pattern SP1 and the second pattern SP2.

The display device in the embodiment of the disclosure may include the first to third light-emitting parts EL1 to EL3 separated from each other with respect to the recess RCS through the separator SPT′. The other light generating layers except a hole injection layer (e.g., the hole injection layer HIL shown in FIG. 5) and a charge generation layer (e.g., the charge generation layer CGL shown in FIG. 5) among a plurality of light generation layers constituting the first to third light-emitting parts EL1 to EL3 may extend while being shared by the first to third light-emitting parts EL1 to EL3. Accordingly, the other light generation layers except the hole injection layer HIL and the charge generation layer CGL may be disposed on the first film SP3 disposed between the first pattern SP1 and the second pattern SP2. As the other light generation layers except the hole injection layer HIL and the charge generation layer CGL are disposed on the first film SP3, a coupling phenomenon occurring between adjacent sub-pixels SPX1 to SPX3 may be prevented.

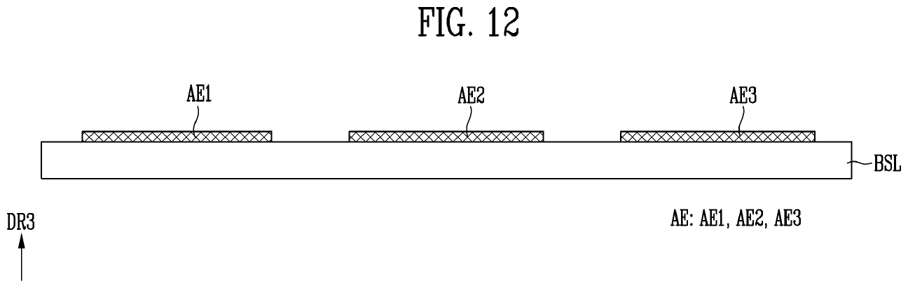

FIGS. 12 to 17 are schematic cross-sectional views illustrating an embodiment of a method of manufacturing a display device in accordance with the disclosure.

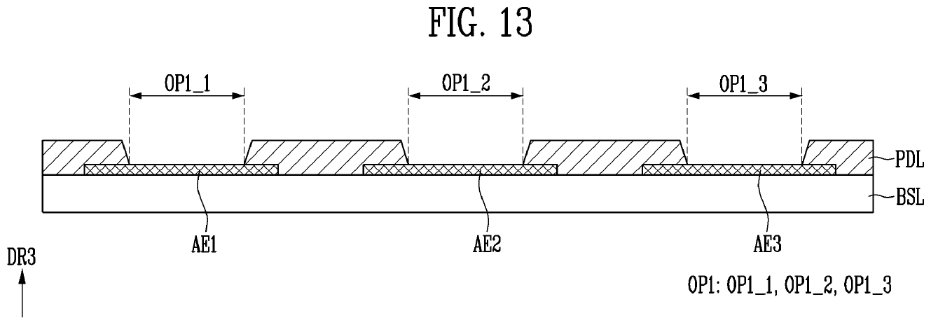

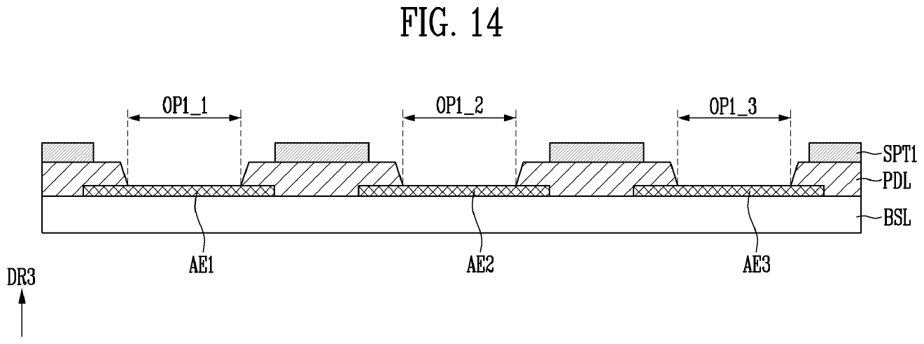

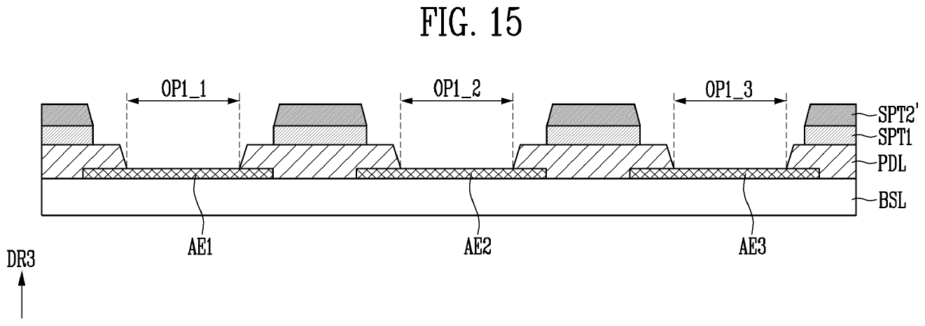

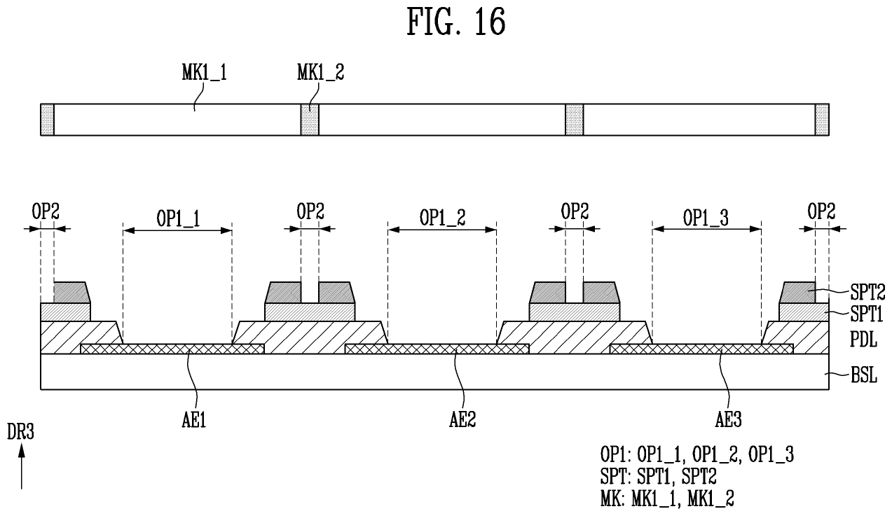

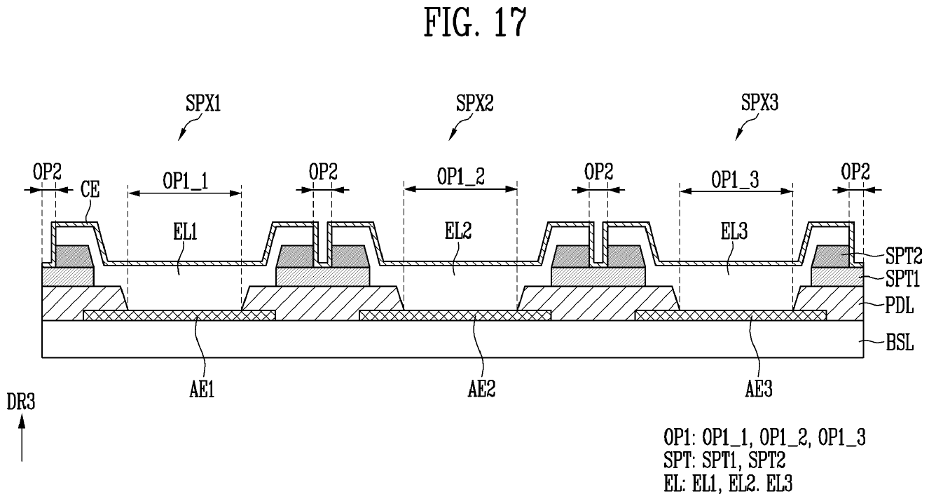

The method of manufacturing the display device in the embodiments of the disclosure may include an operation of forming, on a base substrate BSL, first to third sub-pixel electrodes AE1 to AE3 of respective first to third sub-pixels SPX1 to SPX3 spaced apart from each other in the first direction DR1 (refer to FIG. 12), an operation of forming a pixel defining layer PDL defining first openings OP1 exposing the first to third sub-pixel electrodes AE1 to AE3 (refer to FIG. 13), an operation of forming a first layer SPT1 on the pixel defining layer PDL (refer to FIG. 14), an operation of forming a second layer SPT2 defining a second opening OP2 exposing the first layer SPT1 (refer to FIGS. 15 and 16), and an operation of forming an organic light-emitting part EL including a plurality of light generation layers and a second pixel electrode CE, which are disposed on the first layer SPT1 and the second layer SPT2 (refer to FIG. 17).

Referring to FIG. 12, first to third sub-pixel electrodes AE1 to AE3 may be disposed on a base substrate BSL to be spaced apart from each other in the first direction DR1.

In an embodiment, the base substrate (also referred to as a base layer) BSL may be a rigid or flexible substrate or film. In an embodiment, the base layer BSL may be a rigid substrate including glass or tempered glass, a flexible substrate (or thin film) including plastic or a metal material, or at least one insulating layer. The material and/or property of the base layer BSL are/is not particularly limited. In an embodiment, the base layer BSL may be substantially transparent. The term “substantially transparent” may mean that light may be transmitted with a predetermined transmittance or more. In another embodiment, the base layer BSL may be translucent or opaque. Also, the base layer BSL may include a reflective material in some embodiments. In the disclosure, the base substrate BSL may be designated as a base substrate or a substrate.

Referring to FIG. 13, a pixel defining layer PDL defining first openings OP1 exposing the first to third sub-pixel electrodes AE1 to AE3 may be formed over the first to third sub-pixel electrodes AE1 to AE3. In an embodiment, the first openings OP1 may include a (1_1)^{th} opening OP1_1, a (1_2)^{th} opening OP1_2, and a (1_3)^{th} opening OP1_3. The (1_1)^{th} opening OP1_1 may expose the first sub-pixel electrode AE1. The (1_2)^{th} opening OP1_2 may expose the second sub-pixel electrode AE2. The (1_3)^{th} opening OP1_3 may expose the third sub-pixel electrode AE3. The first openings OP1 may define areas in which light-emitting parts (e.g., the first to third light-emitting parts EL1 to EL3) are formed.

In an embodiment, the pixel defining layer PDL may include an inorganic material. In an embodiment, the pixel defining layer PDL may include at least one of silicon oxide (SiOₓ) and silicon nitride (SiNₓ), for example. In some embodiments, the pixel defining layer PDL may have a multi-layer structure in which a layer including silicon oxide (SiOₓ) and a layer including silicon nitride (SiNₓ) are stacked. However, the disclosure is not limited thereto.

Referring to FIG. 14, a first layer SPT1 may be formed on the pixel defining layer PDL. In an embodiment, the first layer SPT1 may be disposed on a top surface of the pixel defining layer PDL. The first layer SPT1 may include a metal material. The first layer SPT1 may include at least one of various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), or the like, but the disclosure is not limited thereto. The first layer SPT1 may include at least one conductive material among an alloy including the aforementioned metal material, a conductive oxide such as ITO, IZO, ITZO, AZO, GZO, ZTO, or GTO, and a conductive polymer such as PEDOT, but the disclosure is not necessarily limited thereto.

In an embodiment, the first layer SPT1 may be formed on the pixel defining layer PDL through developing and etching processes. A height of the first layer SPT1 may be lower than a height of the pixel defining layer PDL.

Referring to FIG. 15, a second layer SPT2′ may be formed on the first layer SPT1. The second layer SPT2′ may be formed by depositing an inorganic layer on the first layer SPT1. In an embodiment, the second layer SPT2′ may include an inorganic material. The second layer SPT2′ may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In an embodiment, a height of the second layer SPT2′ in the third direction DR3 may be determined according to a thickness of an organic light-emitting part (e.g., an organic light-emitting part EL shown in FIG. 17) which will be described later. In an embodiment, the height of the second layer SPT2′ may become higher as the thickness of the organic light-emitting part EL becomes thicker.

Referring to FIG. 16, a second opening OP2 may be defined by removing at least a portion of the second layer SPT2′. In an embodiment, one area of the second layer SPT2′ may be etched. The etching may be wet etching or dry etching, but the disclosure is not limited to a predetermined example. In an embodiment, light exposure, development, and etching processes on the second layer SPT2′ may be performed. Although not shown in FIG. 16, a photoresist layer including a photosensitive material may be applied on the second layer SPT2′.

A mask MK including a first area MK1_1 and a second area MK1_2 may be used in the light exposure and development processes on the second layer SPT2′. A degree to which the second layer SPT2′ is etched may vary for each area due to a light transmittance difference between the first area MK1_1 and the second area MK1_2 of the mask MK. The second area MK1_2 may be a light-transmitting area, and the first area MK1_1 may be a light-blocking area. As an area overlapping with the second area MK1_2 in the second layer SPT2′ is removed and an area overlapping with the first area MK1_1 remains, the second opening OP2 may be defined in the area corresponding to the second area MK1_2.

Referring to FIG. 17, an organic light-emitting part EL including a plurality of light generation layers may be formed on the first layer SPT1 and the second layer SPT2, and a second pixel electrode CE may be formed on the organic light-emitting part EL.

The organic light-emitting part EL may include a relatively low molecular organic material or a relatively high molecular organic material. The organic light-emitting part EL may be formed through vapor deposition, printing, or slit coating, but the disclosure is not limited thereto.

The organic light-emitting part EL may also be formed in first to third sub-pixels SPX1 to SPX3 and boundary areas therebetween. The organic light-emitting part EL may be physically separated into first to third light-emitting parts EL1 to EL3 by a separator SPT disposed in the boundary areas between the first to third sub-pixels SPX1 to SPX3.

The second pixel electrode CE may be a common electrode commonly formed in the first to third sub-pixels SPX1 to SPX3.

In the display device and the method of manufacturing the same in the embodiments of the disclosure, as the separator SPT or SPT′ is disposed (or formed) between adjacent sub-pixels, at least some of the layers constituting the organic light-emitting part EL may be cut. Accordingly, a lateral leakage phenomenon caused as the organic light-emitting part is commonly provided in the sub-pixels may be reduced or prevented.

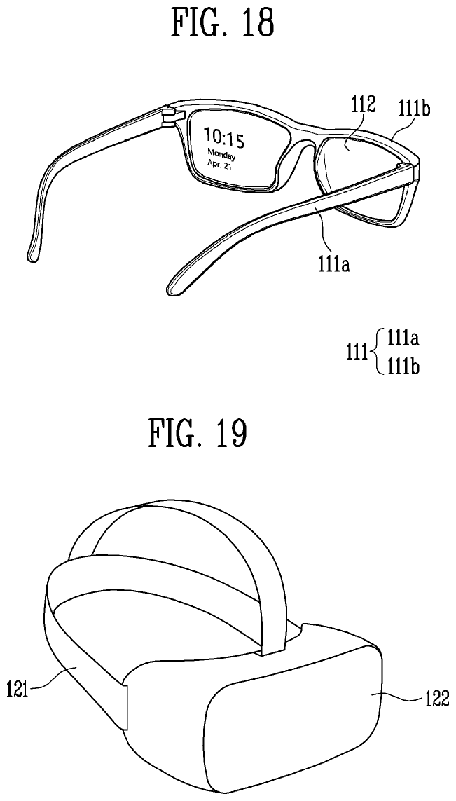

FIGS. 18 and 19 illustrate embodiments of an electronic device including the display device shown in FIG. 1.

Referring to FIG. 18, the display device in accordance with the above-described embodiments may be applied to smart glasses.

The smart glasses include a frame 111 and a lens part 112. The smart glasses are a wearable electronic device which may be worn on the face of a user, and may have a structure in which a portion of the frame 111 is folded or unfolded. In an embodiment, the smart glasses may be a wearable device for augmented reality (“AR”), for example.

The frame 111 may include a housing 111b supporting the lens part 112 and a leg part 111a for allowing the user to wear the smart glasses. The leg part 111a may be connected to the housing 111b by a hinge to be folded or unfolded.

A battery, a touch pad, a microphone, and/or a camera may be built in the frame 111. In addition, a projector for outputting light and/or a processor for controlling a light signal may be built in the frame 111.

The lens part 112 may be an optical member which allows light to be transmitted therethrough or allows light to be reflected thereby. The lens part 112 may include glass and/or transparent synthetic resin.

The display device in accordance with the above-described embodiments may be applied to the lens part 112. In an embodiment, the user may recognize an image displayed by a light signal transmitted from the projector of the frame 111 through the lens part 112. In an embodiment, the user may recognize information including time, data, or the like, which are displayed on the lens part 112, for example.

Referring to FIG. 19, the display device in accordance with the above-described embodiments may be applied to a head mounted display (“HMD”). The HMD may include a head mounted band 121 and a display accommodating case 122. In an embodiment, the HMD is a wearable electronic device which may be worn on the head of a user, for example.

The head mounted band 121 may be connected to the display accommodating case 122, to fix the display accommodating case 122. As shown in FIG. 19, the head mounted band 121 may include a horizontal band and a vertical band to fix the HMD to the head of the user. The horizontal band may be provided to surround a side portion of the head of the user, and the vertical band may be provided to surround a top portion of the head of the user. However, the disclosure is not necessarily limited thereto, and the head mounted band 121 may be implemented in the shape of a glasses frame or a helmet.

The display accommodating case 122 accommodates the display device, and may include at least one lens. The at least one lens may provide an image to the user. In an embodiment, the display device in accordance with the above-described embodiments may be applied to a left-eye lens and a right-eye lens, which are implemented in the display accommodating case 122, for example.

In the display device and the method of manufacturing the same in accordance with the disclosure, as the separator is disposed (or formed) between adjacent sub-pixels, at least some of the layers constituting the organic light-emitting part may be cut. Accordingly, a lateral leakage phenomenon caused as the organic light-emitting part is commonly provided in the sub-pixels may be reduced or prevented.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a sub-pixel;
a first pixel electrode disposed on the substrate;
a pixel defining layer disposed on the first pixel electrode, the pixel defining layer defining a first opening exposing the first pixel electrode;
a separator disposed on a top surface of the pixel defining layer, the separator including:
a first layer disposed on the pixel defining layer; and
a second layer disposed on the first layer, the second layer defining a second opening exposing the first layer;
an organic light-emitting part disposed on the pixel defining layer and the separator, the organic light-emitting part including a plurality of light generation layers; and
a second pixel electrode disposed on the organic light-emitting part.

2. The display device of claim 1, wherein the first layer includes a metal material, and
the second layer includes an inorganic material.

3. The display device of claim 1, wherein at least a portion of the second pixel electrode is disposed in the second opening.

4. The display device of claim 3, wherein the second pixel electrode is disposed directly on the first layer exposed through the second opening.

5. The display device of claim 1, wherein the organic light-emitting part includes a hole injection layer, a hole transport layer, a light-emitting layer, an electron transport layer, a charge generation layer, and an electron injection layer, which are sequentially disposed in a third direction intersecting a first direction, and
wherein at least one of the hole injection layer, the hole transport layer, the light-emitting layer, the electron transport layer, the charge generation layer, and the electron injection layer is not disposed on the first layer exposed through the second opening.

6. The display device of claim 5, wherein the hole injection layer and the charge generation layer are not disposed on the first layer exposed through the second opening.

7. The display device of claim 1, further comprising a reflective electrode of the sub-pixel, which is disposed between the substrate and the first pixel electrode.

8. The display device of claim 7, further comprising an inorganic layer disposed on the substrate,
wherein the substrate includes a silicon substrate, and
wherein the reflective electrode is disposed directly on the substrate.

9. The display device of claim 1, wherein a height of the second layer in a third direction is about 400 nanometers, and
wherein the second opening has a width of about 135 nanometers or less.

10. The display device of claim 1, further comprising:
an encapsulation layer disposed on the second pixel electrode; and
a color filter layer including first to third color filters disposed on the encapsulation layer while being spaced apart from each other in a first direction.

11. A display device comprising:
a substrate including a sub-pixel;
a first pixel electrode disposed on the substrate;
a pixel defining layer disposed on the first pixel electrode, the pixel defining layer defining a first opening exposing the first pixel electrode;
a separator disposed on a top surface of the pixel defining layer, the separator including:
a first pattern and a second pattern disposed on the pixel defining layer, the first pattern and the second pattern being spaced apart from each other in a first direction; and
a first film covering the first pattern and the second pattern;
an organic light-emitting part disposed on the pixel defining layer and the separator, the organic light-emitting part including a plurality of light generation layers; and
a second pixel electrode disposed on the organic light-emitting part.

12. The display device of claim 11, wherein the first pattern and the second pattern include a metal material, and
the first film includes an inorganic material.

13. The display device of claim 12, wherein a recess is defined between the first pattern and the second pattern, and
wherein at least a portion of the second pixel electrode is disposed in the recess.

14. The display device of claim 13, wherein a height of the recess in a third direction intersecting the first direction is about 400 nanometers, and
a width of the recess in the first direction is about 135 nanometers.

15. The display device of claim 13, wherein the first film includes a first part covering the first pattern, a second part covering the second pattern, and a third part covering the pixel defining layer exposed between the first pattern and the second pattern.

16. The display device of claim 15, wherein the organic light-emitting part includes a hole injection layer, a hole transport layer, a light-emitting layer, an electron transport layer, a charge generation layer, and an electron injection layer, which are sequentially disposed in a third direction intersecting the first direction, and
wherein at least one of the hole injection layer, the hole transport layer, the light-emitting layer, the electron transport layer, the charge generation layer, and the electron injection layer is not disposed on the third part of the first film.

17. The display device of claim 16, wherein the hole injection layer and the charge generation layer are not disposed on the third part of the first film.

18. The display device of claim 16, wherein the second pixel electrode is disposed directly on the third part of the first film.

19. A method of manufacturing a display device, the method comprising:
forming a first pixel electrode of a sub-pixel on a substrate;
forming a pixel defining layer defining a first opening exposing the first pixel electrode;
forming a first layer on a top surface of the pixel defining layer;
forming, on the first layer, a second layer defining a second opening exposing the first layer;
forming an organic light-emitting part disposed on the first layer and the second layer, the organic light-emitting part including a plurality of light generation layers; and
forming a second pixel electrode on the organic light-emitting part,
wherein a height of the second layer is in proportion to a height of the organic light-emitting part.

20. The method of claim 19, wherein the forming the second layer defining the second opening includes:
forming an inorganic layer on the first layer; and
defining the second opening by etching and removing a portion of the inorganic layer.
